(19) United States
(12) Patent Application Publication
(10) Pub. No.: US 2018/0261735 A1
(43) Pub. Date: Sep. 13, 2018

(54) Radiation-Emitting Optoelectronic Semiconductor Component and Method for Producing the Same

(71) Applicant: OSRAM Opto Semiconductors GmbH, Regensburg (DE)

(72) Inventors: Thomas SCHWARZ, Regensburg (DE); Frank SINGER, Regenstauf (DE); Stefan ILLEK, Donaustauf (DE); Michael ZIZLSPERGER, Regensburg (DE); Britta GÖÖTZ, Regensburg (DE)

(73) Assignee: OSRAM Opto Semiconductors GmbH, Regensburg (DE)

(21) Appl. No.: 15/533,024

(22) PCT Filed: Dec. 1, 2015
(86) PCT No.: PCT/EP2015/078221

§ 371 Date: Jun. 4, 2017

(30) Foreign Application Priority Data
Dec. 3, 2014 (DE) 102014117764.9

(51) Int. Cl. H01L 33/50; H01L 33/56

(52) U.S. Cl. CPC H01L 33/507; H01L 33/505; H01L 2933/0041; H01L 33/56; H01L 33/502

(57) ABSTRACT

A radiation-emitting optoelectronic semiconductor component and a method for producing the same are disclosed. In an embodiment the semiconductor component includes a radiation passage surface, through which light produced during the operation of the semiconductor component passes, a first barrier layer arranged on a top side of the radiation passage surface and in direct contact with the radiation passage surface, a conversion element arranged on the top side of the first barrier layer, a second barrier layer arranged on the top side of the conversion element and on the top side of the first barrier layer, wherein the first barrier layer and the second barrier layer together completely enclose the conversion element, and wherein the first barrier layer and the second barrier layer are in direct contact with each other at some points.

This patent application is a national phase filing under section 371 of PCT/EP2015/078221, filed Dec. 1, 2015, which claims the priority of German patent application 10 2014 117 764.9, filed Dec. 3, 2014, each of which is incorporated herein by reference in its entirety.

### TECHNICAL FIELD

A radiation-emitting optoelectronic semiconductor component is provided. In addition, a method for producing a radiation-emitting optoelectronic semiconductor component is provided.

### BACKGROUND

Document DE 102012110668 describes a radiation-emitting optoelectronic semiconductor component.

### SUMMARY OF THE INVENTION

Embodiments provide a radiation-emitting optoelectronic semiconductor component having an increased service life. Further embodiments provide a method with which a radiation-emitting optoelectronic semiconductor component may be produced particularly inexpensively.

According to at least one embodiment of the radiation-emitting optoelectronic semiconductor component, the radiation-emitting optoelectronic semiconductor component comprises a radiation passage face, through which light passes which is generated when the semiconductor component is in operation. The radiation-emitting optoelectronic semiconductor component may, for example, be a light-emitting diode. The light generated may be light from the spectral region of UV radiation to infrared radiation. The radiation passage face of the radiation-emitting optoelectronic semiconductor component is a face which is formed, for example, by the outer face of one constituent of the radiation-emitting optoelectronic semiconductor component and through which at least part of the light generated in operation passes when the semiconductor component is in operation. For example, at least 50%, in particular at least 75%, preferably at least 95% of the generated light passes through the radiation passage face.

According to at least one embodiment of the radiation-emitting optoelectronic semiconductor component, the semiconductor component comprises a first barrier layer, which is arranged on a top of the radiation passage face and there is in direct contact at least in places with the radiation passage face. In other words, the first barrier layer may be connected without connecting means to the radiation passage face and thus, for example, to a constituent of the radiation-emitting optoelectronic semiconductor component. The barrier layer is preferably radiation-transmissive. “Radiation-transmissive” means here and hereinafter that at least 50%, in particular at least 75%, preferably at least 95% of the light entering from the radiation passage face into the first barrier layer penetrates the barrier layer without being absorbed in the process. The first barrier layer is, for example, clear and transparent. The barrier layer constitutes a barrier against atmospheric gases and/or moisture. The first barrier layer is therefore impermeable to air and/or water within the bounds of manufacturing tolerances.

According to at least one embodiment of the radiation-emitting optoelectronic semiconductor component, the semiconductor component comprises a conversion element which is arranged on the top, remote from the radiation passage face, of the first barrier layer. For example, the conversion element may be in direct contact with the first barrier layer. The conversion element may then be connected without connecting means to the first barrier layer. The conversion element, for example, comprises particles of at least one conversion material and a matrix material into which the particles of the conversion material have been introduced. In addition, the conversion element may however also consist of the conversion material and be free of a matrix material.

The conversion element is configured to convert light entering from the radiation passage face through the first barrier layer into the conversion element at least in part into light in particular of a greater wavelength. The conversion element then emits secondary radiation, which may form mixed radiation with the light generated when the semiconductor component is in operation and passing through the radiation passage face, i.e., the primary radiation, the mixed radiation, for example, being white light. It is alternatively also possible for the conversion element completely to convert the entering light, within the bounds of manufacturing tolerances, such that only secondary radiation is emitted.

According to at least one embodiment of the radiation-emitting semiconductor component, the semiconductor component comprises a second barrier layer, which is arranged on the top, remote from the first barrier layer, of the conversion element and on the top of the first barrier layer. The second barrier layer may here be in direct contact with the conversion element, i.e., it may in this case be connected without connecting means to the conversion element. The second barrier layer may, like the first barrier layer, be radiation-transmissive, wherein at least 50%, in particular at least 75%, preferably at least 95% of the electromagnetic radiation coming from the conversion element and the first barrier layer passes through the second barrier layer, without being absorbed thereby. The second barrier layer may, for example, be of clear and transparent configuration for this purpose.

Like the first barrier layer, the second barrier layer constitutes a barrier against atmospheric gases and/or moisture and may for this purpose be impermeable to air and/or water.

According to at least one embodiment of the radiation-emitting semiconductor component, the first barrier layer and the second barrier layer jointly completely enclose the conversion element. In other words, the conversion element is completely encapsulated by the two barrier layers and there is no region of the outer face of the conversion element which is not enveloped by one of the two barrier layers. In this case, it is also possible for the two barrier layers to completely cover the outer face of the conversion element, within the bounds of manufacturing tolerances, and to be in direct contact with the conversion element over the entire outer face of the conversion element, within the bounds of manufacturing tolerances, wherein the first or the second barrier layer is in places in direct contact with the conversion element.

According to at least one embodiment of the radiation-emitting optoelectronic semiconductor component, the first barrier layer and the second barrier layer are in places in direct contact with one another. In other words, at the mutually facing surfaces the first barrier layer and the second barrier layer are in places in direct contact with the conversion element and in places in direct contact with one another. The conversion element is thus arranged, as it were, in a cavity enclosed by the two barrier layers.

In other words, the two barrier layers may be bonded together at least in places. A “bonded connection” is here and hereinafter a connection at which the connection components are held together by atomic and/or molecular forces. In particular, a bonded connection may provide hermetic sealing of a space between two connection components. A bonded connection is, for example, a van der Waals connection. A bonded connection in particular cannot be undone non-destructively. In other words, the connection components can only be separated using a chemical solvent and/or by destruction.

According to at least one embodiment of the radiation-emitting semiconductor component, the semiconductor component comprises a radiation passage face, through which light passes which is generated when the semiconductor component is in operation, a first barrier layer, which is arranged on a top of the radiation passage face and there is in direct contact at least in places with the radiation passage face, a conversion element, which is arranged on the top, remote from the radiation passage face, of the first barrier layer, and a second barrier layer, which is arranged on the top, remote from the first barrier layer, of the conversion element and on the top of the first barrier layer, wherein the first barrier layer and the second barrier layer jointly completely enclose the conversion element and the first barrier layer and the second barrier layer are in places in direct contact with one another.

In the case of the radiation-emitting optoelectronic semiconductor component described here, the conversion element is arranged between two barrier layers, which may protect the conversion element from external influences such as atmospheric gases and moisture. In this case, the first barrier layer is in direct contact with a constituent of the radiation-emitting optoelectronic semiconductor component and may be produced, for example, directly on this constituent. The conversion element may then be produced, for example, directly on the first barrier layer and the second barrier layer may be produced directly on the first barrier layer and the conversion element.

This means that it is not necessary to manufacture the conversion element separately from the semiconductor component. The conversion element does not therefore have to be self-supporting, but rather the barrier layers may be flexible, resilient sealing layers, which retain their property of protecting against atmospheric gases and/or moisture even under cyclic loading when the semiconductor component is in operation.

The semiconductor component described here is therefore distinguished inter alia by its particularly long service life. Furthermore, sensitive conversion materials such as, for example, organic conversion materials or “quantum dot converters” may be used in the conversion element, which materials benefit from the increased protection from atmospheric gases and/or moisture provided by the barrier layers and thereby have an increased service life in the semiconductor component.

According to at least one embodiment of the radiation-emitting optoelectronic semiconductor component, the first barrier layer and the second barrier layer are in direct contact with one another in a contact region, wherein the contact region completely surrounds the conversion element in lateral directions. The contact region here encloses the conversion element, for example, in the manner of a frame, wherein the profile of the contact region does not here have to be rectangular.

The conversion element thus covers only a part of the top facing it of the first barrier layer and the conversion element covers only a part of the bottom facing it of the second barrier layer. The first and the second barrier layers thus have a larger area than the conversion element. In regions in which the top of the first barrier layer and the bottom of the second barrier layer are not in contact with the conversion element, the first and second barrier layers are in direct contact with one another, wherein in the region of direct contact the contact region is formed between the two barrier layers.

According to at least one embodiment of the radiation-emitting semiconductor component, the conversion element is in direct contact with the first barrier layer and the second barrier layer. In other words, no further layers are arranged respectively between the conversion element and the two barrier layers, and it is in particular possible for no, for example, air-filled gaseous inclusions to be located between the barrier layers and the conversion elements.

In particular, it is possible for the two barrier layers to directly adjoin one another in the contact region and in each case to directly adjoin the conversion element outside the contact region. This makes it possible for the connection between the barrier layers and the conversion element to lack any connection means and for these constituents of the semiconductor component to be particularly well connected together mechanically. In this case, the barrier layers and the conversion element cannot, in particular, be detached from one another in a non-destructive manner, i.e., only by destroying at least one of the constituents can the assembly of barrier layers and conversion element be broken. In addition, it is possible for the first barrier layer not to be connected non-destructively with a further constituent of the radiation-emitting optoelectronic semiconductor component. The radiation-emitting optoelectronic semiconductor component is thus of an overall particularly robust configuration.

According to at least one embodiment of the radiation-emitting optoelectronic semiconductor component, a water vapor transmission rate into the conversion element amounts at most to 1×10-3 g/m2/day, preferably at most 3×10-4 g/m2/day. In other words, the conversion element is outwardly sealed by the barrier layers. The barrier layers and the contact region between the barrier layers are configured in such a way that the water vapor transmission rate is particularly low. This is possible as a result of the material selection for the barrier layers and the arrangement of the barrier layers directly adjacent one another in the contact region.

According to at least one embodiment of the radiation-emitting optoelectronic semiconductor component, the first barrier layer and the second barrier layer are formed with the same material or they consist of the same material. In other words, the first and second barrier layer share at least one material constituent or consist of the same material. This makes it possible for the first barrier layer and the second barrier layer to adhere particularly well together in the contact region, so enabling the stated low water vapor transmission rates.

According to at least one embodiment of the radiation-emitting optoelectronic semiconductor component, the first and/or the second barrier layer are formed in particular with one of the following materials. In other words, the first and/or the second barrier layer comprise at least one of the following materials or consist of at least one of the following materials: a parylene, a PVC, a polyvinylidene chloride, a polyvinyl alcohol, a polysilazane, an ormocer or an epoxide.

According to at least one embodiment of the radiation-emitting optoelectronic semiconductor component, the first barrier layer and/or the second barrier layer have a modulus of elasticity of at most 5.0 GPa. In other words, the barrier layers comprise particularly resilient sealing layers. The barrier layers are in particular resilient in comparison with conventional encapsulation materials such as glass, silicon dioxide, silicon nitride or aluminum oxide. It is therefore possible to dispense with expensive materials and processes for the production and application thereof in the semiconductor component.

The barrier layers in particular do not comprise glasses or metals which are connected together using complex methods such as anodic bonding, soldering, welding or optical contact bonding. Due to the resilience of the barrier layers, the risk of cracking in the barrier layers is reduced compared to hard barrier layers, which are formed, for example, with Al₂O₃ by way of ALD (Atomic Layer Deposition). The often marked difference in the coefficient of thermal expansion between constituents of the radiation-emitting optoelectronic semiconductor component leads to different thermal expansions of the constituents when in operation. Due to the resiliently configured barrier layers, however, the risk of cracking under cyclic loading is greatly reduced.

According to at least one embodiment of the radiation-emitting optoelectronic semiconductor component, the conversion element comprises wavelength-converting quantum dots or consists of wavelength-converting quantum dots.

Wavelength-converting quantum dots comprise a sensitive conversion material. Preferably, the quantum dots comprise nanoparticles, i.e., particles with a size in the nanometer range with a particle diameter d50 measured in Q0 of, for example, between at least 1 nm and at most 1000 nm. The quantum dots comprise a semiconductor core, which has wavelength-converting characteristics. The semiconductor core may, for example, be formed with CDSE, CDS, EANS and/or ENP. The semiconductor core may be encased in a plurality of layers. In other words, the semiconductor core may be completely or almost completely covered by further layers at its outer faces.

A first encasing layer of a quantum dot is, for example, formed with an inorganic material, such as, for example, ZNS, CDS and/or CDSE, and serves in creation of the quantum dot potential. The first encasing layer and the semiconductor core are almost completely enclosed at the exposed outer face by at least one second encasing layer. The second layer may, for example, be formed with an organic material, such as, for example, cystamine or cysteine, and serves to improve the solubility of the quantum dots in, for example, a matrix material and/or a solvent. In this case, it is possible for a spatially uniform distribution of the quantum dots in a matrix material to be improved as a result of the second encasing layer.

The matrix material may, for example, be formed with at least one of the following substances: acrylate, silicone or hybrid materials such as ormocers.

This results in the problem that the second encasing layer of the quantum dot could oxidize on contact with air and thereby be destroyed, so reducing the solubility of the quantum dots. This would then, for example, result in agglomeration of the quantum dots, i.e., lump formation, in the matrix material. In the case of lump formation, the quantum dots would draw too close to one another in the matrix material and the excitation energies might be exchanged in a radiationless manner between the quantum dots. This would result in efficiency loss during wavelength conversion.

Destruction of the second encasing layer may be prevented by hermetic sealing of the quantum dots from the air surrounding the conversion element. This hermetic sealing proceeds in the present case by bonded connection of the two barrier layers.

Alternatively or in addition to quantum dots as conversion material, the conversion element may contain an organic conversion material. The organic conversion material for, example, comprises organic dyes. Such organic dyes are, for example, also known from German published specification DE 10 2007 049 005 A1, the disclosure content of which is hereby included by reference.

According to at least one embodiment of the radiation-emitting optoelectronic semiconductor component, the semiconductor component comprises a radiation-emitting semiconductor chip and a radiation-transmissive enveloping body, which surrounds the semiconductor chip in places, wherein an outer face, remote from the semiconductor chip, of the radiation-transmissive enveloping body comprises the radiation passage face and the first barrier layer is in direct contact with the enveloping body. The enveloping body may thus be arranged between the semiconductor chip and the conversion element. In particular, the conversion element may be arranged spaced from the semiconductor chip by means of the enveloping body. The enveloping body may, for example, be formed around the semiconductor chip by methods such as injection molding or compression molding. The radiation-transmissive enveloping body may here be formed with a material such as epoxide, silicone or an epoxide-silicone hybrid material. The radiation-transmissive enveloping body may be filled with scattering and/or converting particles. The first barrier layer is preferably located in direct contact with the enveloping body, such that the first barrier layer is connected without connecting means to the enveloping body.

The enveloping body may be of curved configuration. In particular, the enveloping body may comprise a curved potting compound. The enveloping body may be curved away from the semiconductor chip or towards it. In other words, the enveloping body may have a different thickness in the region of the semiconductor body than in lateral edge regions of the enveloping body. Curvature of the enveloping body may in particular increase the probability of the exit of electromagnetic radiation from the enveloping body. In addition, curvature may make it possible for a distance between the radiation-emitting semiconductor chip and the conversion element to be increased, so as to avoid excessive radiance at the conversion element.

In this respect, it is in particular possible for the material of the radiation-transmissive enveloping body to differ from the material of the first barrier layer. In other words, the radiation-transmissive enveloping body and the first barrier layer are then formed of different materials. The material of the radiation-transmissive enveloping body may thus be particularly well conformed to the optical requirements of the optoelectronic semiconductor component and the material of the first barrier layer is selected in terms of its properties providing protection against moisture and/or atmospheric gases.

According to at least one embodiment of the radiation-emitting optoelectronic semiconductor component, the radiation-emitting optoelectronic semiconductor component comprises a radiation-emitting semiconductor chip, wherein an outer face of the radiation-emitting semiconductor chip comprises the radiation passage face and the first barrier layer is in direct contact with the radiation-emitting semiconductor chip. In other words, in this embodiment the radiation-emitting semiconductor chip is not surrounded at least in places by a radiation-transmissive enveloping body and the first barrier layer at least in places directly adjoins the radiation-emitting semiconductor chip. In this way, it is possible to arrange the conversion element particularly close to the radiation-emitting semiconductor chip.

The radiation-emitting semiconductor chip, for example, comprises a light-emitting diode chip, which in operation emits electromagnetic radiation from the spectral region of UV radiation to visible light, for example, blue light. The radiation-emitting optoelectronic semiconductor component may here comprise a plurality of radiation-emitting semiconductor chips, which may be identically or differently embodied.

According to at least one embodiment of the radiation-emitting optoelectronic semiconductor component, the semiconductor component comprises a package body, which comprises a cavity in which the radiation-emitting semiconductor chip is arranged. Furthermore, the radiation-emitting optoelectronic semiconductor component may comprise a radiation-emitting semiconductor chip, such as, for example, a light-emitting diode chip. The package body may in this case surround the radiation-emitting semiconductor chip, for example, in lateral directions, i.e., to the sides. The outer faces of the package body facing the radiation-emitting semiconductor chip may be reflective for electromagnetic radiation generated in the radiation-emitting semiconductor chip. The package body may be arranged spaced relative to the radiation-emitting semiconductor chip, or the package body is in direct contact with the radiation-emitting semiconductor chip at side faces of the radiation-emitting semiconductor chip. For example, the first barrier layer is located in part within the cavity. This may allow protection of the first barrier layer from mechanical damage.

According to at least one embodiment of the radiation-emitting optoelectronic semiconductor component, the first barrier layer is arranged at least in places in the cavity and/or is in direct contact with the package body. In other words, it is possible for at least the first barrier layer likewise to be surrounded laterally in places by the package body. The first barrier layer may thereby be mechanically protected by the package body at least in places. Additionally or alternatively, it is possible for the first barrier layer in places to be in direct contact with the package body. In other words, the first barrier layer and the package body are then connected together without a connecting means. The first barrier layer is then in direct contact with a further constituent of the radiation-emitting optoelectronic semiconductor component, for example, the radiation-transmissive enveloping body and/or the radiation-emitting semiconductor chip. As a result of the contact between the first barrier layer and a plurality of constituents of the radiation-emitting optoelectronic semiconductor component, the first barrier layer adheres particularly well and the mechanical stability of the radiation-emitting semiconductor component is increased in this way.

According to at least one embodiment of the radiation-emitting optoelectronic semiconductor component, the cavity comprises an opening remote from the radiation-emitting semiconductor chip, wherein the opening is covered over at least 95% of its area by the conversion element. In other words, the conversion element fills virtually the entire area of the opening and almost all the electromagnetic radiation generated in the optoelectronic semiconductor component has in this way to pass through the conversion element in order to leave the optoelectronic semiconductor component. In this way, it is possible to prevent a significant proportion of unconverted light from exiting the semiconductor component in the region between package body and conversion element, for example, via the first barrier layer. Leakage of, for example, blue, unconverted light is thus reduced.

According to at least one embodiment of the radiation-emitting optoelectronic semiconductor component, the latter comprises at least one further conversion element, which is arranged on the top, remote from the radiation passage face, of the second barrier layer, and at least one further barrier layer, which is arranged on the top, remote from the second barrier layer, of the further conversion element and on the top of the second barrier layer, wherein the second barrier layer and the further barrier layer jointly completely enclose the further conversion element, and the second barrier layer and the further barrier layer are in places in direct contact with one another.

All the features are disclosed for the further barrier layer and the further conversion element which are also disclosed for the conversion element and for the first barrier layer and the second barrier layer.

In this case, it is in particular possible for the further conversion element to be formed with a conversion material which is more sensitive, for example, to electromagnetic radiation, in particular UV radiation, and/or more sensitive to elevated temperatures than the conversion material of the conversion element. In particular, it is possible for the semiconductor component to comprise a multiplicity of conversion elements and barrier layers which are arranged stacked on one another in the described manner. In this case, it is possible for the different conversion elements to comprise different conversion materials, wherein a conversion element is further away from the radiation passage face, the more sensitive is the conversion material used in the conversion element. Alternatively, it is possible for all the conversion elements to be of identical construction. Furthermore, it is possible for mutually adjacent barrier layers each to be in direct contact with one another in a contact region, wherein the contact region completely surrounds in lateral directions the conversion element enclosed between the adjacent barrier layers. The enclosed conversion element may here in each case be in direct contact with the adjacent barrier layers.

Methods for producing radiation-emitting optoelectronic semiconductor components are additionally provided. The methods may in particular serve in producing here-described optoelectronic semiconductor components, such that the features disclosed for the optoelectronic semiconductor components are also disclosed for the method and vice versa.

According to at least one embodiment of the method for producing a radiation-emitting optoelectronic semiconductor component, the method comprises a method step in which the first barrier layer is applied to the radiation passage face. The first barrier layer is here preferably applied in a parallel process to the radiation passage faces of a multiplicity of radiation-emitting optoelectronic semiconductor components to be produced. Application may proceed, for example, by deposition under a vacuum or large-area spraying directly onto and over the entire surface of a constituent of the radiation-emitting optoelectronic semiconductor component which comprises the radiation passage face. This results in a direct connection between the constituent or the constituents of the optoelectronic semiconductor component onto which the first barrier layer is applied and the first barrier layer.

According to at least one embodiment of the method, in a further method step the conversion material is applied patterned onto the top, remote from the radiation passage face, of the first barrier layer to form the conversion element, such that the first barrier layer in places remains uncovered by the conversion element. In other words, the conversion material is not applied over the entire surface of the outer face, facing the subsequent conversion element, of the first barrier layer, but rather a part of the first barrier layer remains uncovered by the conversion material. In addition, it is possible for patterned application of the conversion material to proceed in such a way that the conversion material is arranged in specific patterns on the first barrier layer. Patterned application may proceed, for example, by dispensing, screen printing, stencil printing, jetting or spraying with a mask. In particular, the conversion material, and thus the conversion element to be produced, then adjoins the first barrier layer directly in places and is connected therewith without a connecting means.

According to at least one embodiment of the method, in a further method step the second barrier layer is applied onto the top, remote from the first barrier layer, of the conversion element and onto the regions of the first barrier layer not covered by the conversion element. Here too, application of the second barrier layer, for example, by vacuum deposition or large-area spraying may proceed in a parallel process in which the material of the second barrier layer is applied for a multiplicity of optoelectronic semiconductor components to be produced.

According to at least one embodiment of the method for producing a radiation-emitting optoelectronic semiconductor chip, the method comprises the following steps: application of the first barrier layer to the radiation passage face, patterned application of conversion material to the top, remote from the radiation passage face, of the first barrier layer to form the conversion element, such that the first barrier layer in places remains uncovered by the conversion element, application of the second barrier layer to the top, remote from the first barrier layer, of the conversion element and to regions of the first barrier layer not covered by the conversion element.

The method may here be performed in particular in the stated sequence, i.e., the finished conversion element is produced directly on at least one constituent of the optoelectronic semiconductor component and not produced separately from the other constituents of the optoelectronic semiconductor component and then connected therewith, for example, by a connecting means.

According to at least one embodiment of the method for producing a radiation-emitting optoelectronic semiconductor component, the method comprises a step wherein the actual value of the light characteristic curve of the mixed light generated by the radiation-emitting semiconductor chip and the conversion element during operation of the semiconductor component is determined. The light characteristic curve may, for example, be the colour location and/or the color temperature of the mixed light generated by the radiation-emitting semiconductor chip and the conversion element when in operation.

In a further method step, this actual value is then compared with a setpoint and in a subsequent method step patterned application of further conversion material takes place to achieve the setpoint.

These method steps may be repeated until the measured actual value corresponds with the setpoint within a predeterminable error tolerance.

Thus, for example, control of the color location or of the color temperature of the resultant mixed light proceeds by post-dispensing or post-spraying prior to sealing of the arrangement with the second barrier layer. The purposeful establishment of a desired color location is thereby particularly simply possible.

In the present case, the conversion element is thus not produced in a complex way separately from the other constituents of the semiconductor component, but rather production proceeds directly on the semiconductor component, whereby even during production a light characteristic curve of the generated mixed light may be determined. Since enclosure of the conversion element with the second barrier layer proceeds only once the desired light characteristic curve has been achieved, post-adjustment of the conversion element is particularly simply possible through additional application of conversion material.

Using the method described here, radiation-emitting optoelectronic semiconductor components may be produced in which conversion of electromagnetic radiation takes place directly in the semiconductor component in the immediate vicinity of the optoelectronic semiconductor chip, so simplifying the system and reducing costs.

### BRIEF DESCRIPTION OF THE DRAWINGS

The radiation-emitting optoelectronic semiconductor components described here and the method described here are explained in greater detail below with reference to exemplary embodiments and the associated figures.

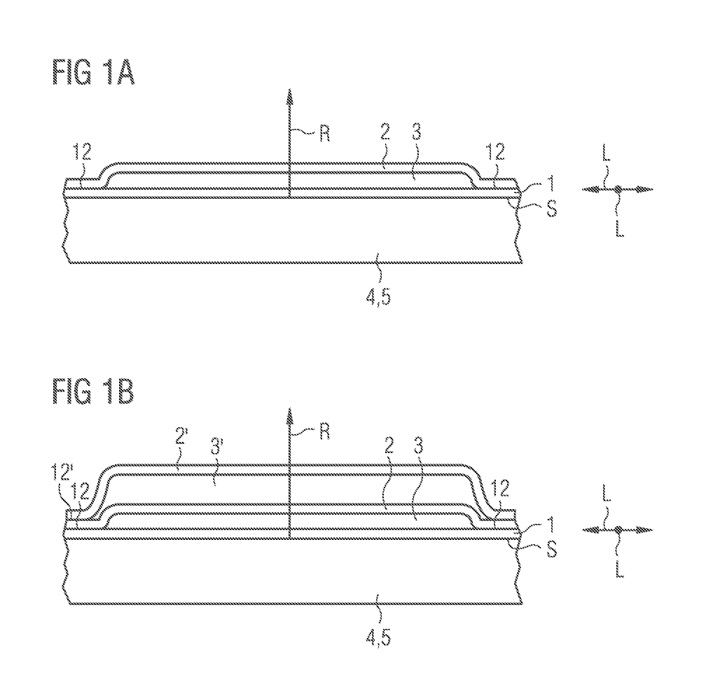

The schematic sectional representations of FIGS. 1A, 1B, 2 and 3 show exemplary embodiments of radiation-emitting optoelectronic semiconductor components described here.

Identical, similar or identically acting elements are provided with identical reference numerals in the figures. The figures and the size ratios of the elements illustrated in the figures relative to one another are not to be regarded as being to scale. Rather, individual elements may be illustrated on an exaggeratedly large scale for greater ease of depiction and/or better comprehension.

### DETAILED DESCRIPTION OF ILLUSTRATIVE EMBODIMENTS

The principle of an optoelectronic semiconductor component described here is explained with reference to the schematic sectional representation of FIG. 1A. The optoelectronic semiconductor component comprises a radiation passage face S. The radiation passage face S may, for example, be the outer face of a radiation-emitting semiconductor chip 4 and/or the outer face of a radiation-transmissive enveloping body 5. The first barrier layer 1 is applied to the radiation passage face S, said first barrier layer 1 directly adjoining the radiation passage face S and being connected with the associated constituents, which comprise the radiation passage face S, without a connecting means and in particular by bonding. The first barrier layer 1 is applied, for example, by a method described here.

Conversion material for forming the conversion element 3 is then applied to part of the top, remote from the radiation passage face S, of the first barrier layer 1, such that the first barrier layer 1 is not completely covered by the conversion material. To establish a suitable thickness of the conversion element 3, a method described here may be used in which, during application of the conversion material, the actual value of a light characteristic curve is compared with a setpoint and the application of conversion material is stopped as soon as the actual value corresponds to the setpoint within a predeterminable error tolerance.

In a further method step, a second barrier layer 2 is applied to the free surface, remote from the radiation passage face S, of the first barrier layer 1 and of the conversion element 3.

The semiconductor device then comprises a first barrier layer 1, which has been applied directly to the radiation passage face, and a conversion element 3, which is arranged between the first barrier layer 1 and the second barrier layer 2. The two barrier layers may each thereby be bonded together and to the conversion element 3.

In the region not covered by the conversion element of the top, remote from the radiation passage face S, of the first barrier layer 1, a contact region 12 is formed between the first barrier layer 1 and the second barrier layer 2, in which the two barrier layers directly adjoin one another. The contact region 12 completely surrounds the conversion element 3 in lateral directions, i.e., to the sides.

In the schematic sectional representation of FIG. 1B of the radiation-emitting optoelectronic semiconductor component, the latter comprises at least one further conversion element 3′, which is arranged on the top, remote from the radiation passage face, of the second barrier layer 2, and at least one further barrier layer 2′, which is arranged on the top, remote from the second barrier layer 2, of the further conversion element 3′ and on the top of the second barrier layer 2, wherein the second barrier layer 2 and the further barrier layer 2′ jointly completely enclose the further conversion element 3′, and the second barrier layer 2 and the further barrier layer 2′ are in places in direct contact with one another.

In this case, it is in particular possible for the further conversion element 3′ to be formed with a conversion material 3 which is more sensitive, for example, to electromagnetic radiation, in particular UV radiation, and/or more sensitive to elevated temperatures than the conversion material of the conversion element 3. The mutually adjacent barrier layers 2, 2′ are in direct contact with one another in a further contact region 12′, wherein the contact region completely surrounds the further conversion element 3′ in lateral directions between the adjacent barrier layers 2, 2′. The enclosed further conversion element 3′ may in this case be in direct contact with each of the adjacent barrier layers 2, 2′.

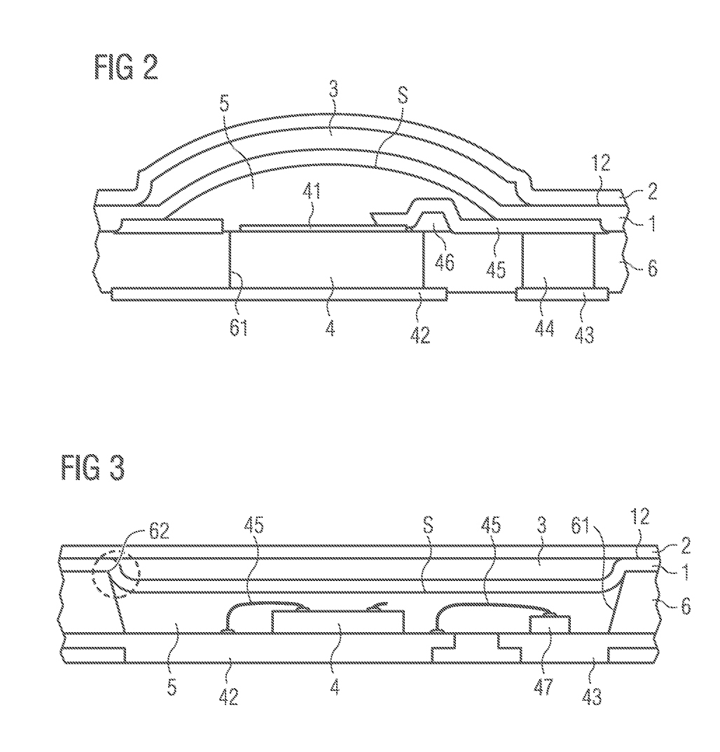

The schematic sectional representation of FIG. 2 shows a radiation-emitting optoelectronic semiconductor component, which is of “chip in frame” (CIF) construction.

Such a component is described in a different context, for example, in document DE 10 2012 215 524 A1, the disclosure content of which, as regards the structure of a component of “chip in frame” construction, is hereby explicitly included by reference. In particular, a “chip in frame” component comprises a molding as package body 6, which may be formed, for example, with a silicone and/or an epoxy resin. Such materials have the disadvantage of not being hermetically sealed, air and/or moisture thus being able to penetrate through the molding. If a non-hermetically sealed conversion element is used in such a “chip in frame” component, destruction of the conversion material may thus occur on use of a sensitive conversion material.

In this case, the semiconductor component comprises the radiation-emitting semiconductor chip 4, which is embedded in a package body 6 which comprises a cavity 61 for the chip. The side faces of the radiation-emitting semiconductor chip 4 may here directly adjoin the package body 6, which may, for example, be radiation-reflective. The radiation-emitting semiconductor chip 4 is connected at its top to the contacting element 41, which is, for example, radiation-transmissive and to this end may comprise a transparent conductive oxide. Via a contact element, for example, a bond pad 46, the contacting element 41 is connected electrically conductively to the contacting element 45, which extends from the radiation-emitting semiconductor chip 4 over the package body 6 to a through-via 44.

On the top, facing the contacting element 41, of the radiation-emitting semiconductor chip 4 the radiation-transmissive enveloping body 5 is formed, which in this case takes the form of a curved potting compound. Due to the curvature of the potting compound, the probability of the exit of electromagnetic radiation is increased. On the bottom, remote from the enveloping body 5, of the radiation-emitting semiconductor chip and the through-via 44, connection points 42, 43 are arranged for surface mounting of the semiconductor component.

The enveloping body 5 of curved configuration further ensures that the distance between the radiation-emitting semiconductor chip 4 and the conversion element 3 is increased, so avoiding excessive radiance at the conversion element 3. In this way, the described design is particularly suitable for the use of sensitive conversion materials such as, for example, quantum dot converters. The enveloping body 5 of curved configuration further allows homogenization of the emitted mixed light in terms of the color of the light, depending on viewing angle.

The first barrier layer 1 is in direct contact with regions of the radiation-transmissive enveloping body 5 and of the package body 6 and of the contacting element 45. In particular, the first barrier layer 1 completely covers the top of the semiconductor device, such that it has a particularly large contact area with the constituents of the semiconductor component and is thus connected mechanically particularly firmly with these constituents. The use of resilient materials to form the first and second barrier layers 1, 2 furthermore allows the conversion element to follow the curvature of the enveloping body 5.

A further exemplary embodiment of a semiconductor device described here is explained in greater detail with reference to the schematic sectional representation of FIG. 3. In this exemplary embodiment, unlike in the exemplary embodiment of FIG. 2, the package body 6 is spaced laterally from the radiation-emitting semiconductor chip 4 and the cavity of the package body 6 is filled in places with the radiation-transmissive enveloping body 5.

The first barrier layer 1 is located partially within the cavity and in this way is particularly well protected from mechanical damage. In addition, the second barrier layer 2 may be of planar construction. In other words, it is possible for an outer face of the second barrier layer 2 to be a planar face which, within the bounds of manufacturing tolerances, does not comprise any projections, depressions, notches and/or bulges. The first barrier layer 1 extends along the enveloping body 5, the outer face of which, remote from the semiconductor chip 4, forms the radiation passage face S. Furthermore, the first barrier layer 1 is in direct contact with the package body 6. The conversion element 3 is arranged over a particularly large area of the radiation-emitting semiconductor chip 4 and covers at least 95% of the opening 62 of the cavity 61 of the package body 6.

In this exemplary embodiment too, the semiconductor device is completely covered at its top by the material of the first barrier layer 1. The contact region 12 between the first barrier layer 1 and the second barrier layer 2, which laterally completely surrounds the conversion element 3, is located in the region above the package body 6.

The description made with reference to exemplary embodiments does not restrict the invention to these embodiments. Rather, the invention encompasses any novel feature and any combination of features, including in particular any combination of features in the claims, the embodiments and the exemplary embodiments, even if this feature or this combination is not itself explicitly indicated in the claims, the embodiments or the exemplary embodiments.

1-16. (canceled)

17. A radiation-emitting optoelectronic semiconductor component comprising:
a radiation passage face, through which light passes which is generated when the semiconductor component is in operation;
a first barrier layer arranged on top of the radiation passage face and in direct contact with the radiation passage face at least in places;
a conversion element arranged on top, remote from the radiation passage face, of the first barrier layer; and
a second barrier layer arranged on top, remote from the first barrier layer, of the conversion element and on the top of the first barrier layer,
wherein the first barrier layer and the second barrier layer jointly completely enclose the conversion element,
wherein the first barrier layer and the second barrier layer are in places in direct contact with one another, and
wherein the conversion element comprises wavelength-converting quantum dots.

18. The radiation-emitting optoelectronic semiconductor component according to claim 17, wherein the wavelength-converting quantum dots comprise a semiconductor core, which has wavelength-converting characteristics, wherein the semiconductor core is surrounded by a first encasing layer comprising an inorganic material, and wherein the first encasing layer is enclosed by a second encasing layer comprising an organic material.

19. The radiation-emitting optoelectronic semiconductor component according to claim 17, wherein the first barrier layer and the second barrier layer are in direct contact with one another in a contact region, and wherein the contact region completely surrounds the conversion element in lateral directions.

20. The radiation-emitting optoelectronic semiconductor component according to claim 17, wherein the conversion element is in direct contact with the first barrier layer and the second barrier layer.

21. The radiation-emitting optoelectronic semiconductor component according to claim 17, wherein a water vapor transmission rate into the conversion element amounts to at most 1×10⁻³ g/m²/day.

22. The radiation-emitting optoelectronic semiconductor component according to claim 17, wherein the first barrier layer and the second barrier layer comprise the same material.

23. The radiation-emitting optoelectronic semiconductor component according to claim 17, wherein the first barrier layer and/or the second barrier layer has a modulus of elasticity of at most 5.0 GPa.

24. The radiation-emitting optoelectronic semiconductor component according to claim 17, further comprising:
a radiation-emitting semiconductor chip; and
a radiation-transmissive enveloping body surrounding the semiconductor chip in places, wherein an outer face, remote from the semiconductor chip, of the radiation-transmissive enveloping body comprises the radiation passage face, and wherein the first barrier layer is in direct contact with the enveloping body.

25. The radiation-emitting optoelectronic semiconductor component according to claim 24, wherein the enveloping body is of curved configuration.

26. The radiation-emitting optoelectronic semiconductor component according to claim 17, further comprising a radiation-emitting semiconductor chip, wherein an outer face of the radiation-emitting semiconductor chip comprises the radiation passage face, and wherein the first barrier layer is in direct contact with the radiation-emitting semiconductor chip.

27. The radiation-emitting optoelectronic semiconductor component according to claim 17, further comprising:
a radiation-emitting semiconductor chip; and
a package body comprising a cavity, in which the radiation-emitting semiconductor chip is arranged, wherein the first barrier layer is arranged at least in places in the cavity and/or is in direct contact with the package body.

28. The radiation-emitting optoelectronic semiconductor component according to claim 27, wherein the cavity comprises an opening remote from the radiation-emitting semiconductor chip, and wherein the opening is covered over at least 95% of its area by the conversion element.

29. The radiation-emitting optoelectronic semiconductor component according to claim 27, wherein the first barrier layer is arranged at least in part within the cavity.

30. The radiation-emitting optoelectronic semiconductor component according to claim 17, further comprising:
a further conversion element arranged on top, remote from the radiation passage face, of the second barrier layer; and
a further barrier layer arranged on top, remote from the second barrier layer, of the further conversion element and on the top of the second barrier layer,
wherein the second barrier layer and the further barrier layer jointly completely enclose the further conversion element, and wherein the second barrier layer and the further barrier layer are in places in direct contact with one another.

31. A method for producing the radiation-emitting optoelectronic semiconductor component according to claim 17, the method comprising:
applying the first barrier layer to the radiation passage face;
forming a conversion material on top, remote from the radiation passage face, of the first barrier layer thereby forming the conversion element such that the first barrier layer remains uncovered by the conversion element in places; and
applying the second barrier layer to top, remote from the first barrier layer, of the conversion element and to regions of the first barrier layer not covered by the conversion element.

32. The method for producing the radiation-emitting optoelectronic semiconductor component according to claim 31, the method comprising:
prior to applying the second barrier layer;
determining an actual value of a light characteristic curve of a mixed light generated by a radiation-emitting semiconductor chip and the conversion element when the semiconductor chip is in operation;
comparing the actual value with a setpoint; and
providing further conversion material to achieve the setpoint.

33. A radiation-emitting optoelectronic semiconductor component comprising:
a radiation passage face, through which light passes which is generated when the semiconductor component is in operation;
a first barrier layer arranged on top of the radiation passage face and in direct contact with the radiation passage face at least in places;
a conversion element arranged on top, remote from the radiation passage face, of the first barrier layer; and
a second barrier layer arranged on top, remote from the first barrier layer, of the conversion element and on the top of the first barrier layer,
wherein the first barrier layer and the second barrier layer jointly completely enclose the conversion element,
wherein the first barrier layer and the second barrier layer are in places in direct contact with one another, and
wherein the conversion element consists essentially of wavelength-converting quantum dots.

34. A radiation-emitting optoelectronic semiconductor component comprising:
a radiation passage face, through which light passes which is generated when the semiconductor component is in operation;
a first barrier layer arranged on top of the radiation passage face in direct contact with the radiation passage face at least in places;
a conversion element arranged on top, remote from the radiation passage face, of the first barrier layer; and
a second barrier layer arranged on top, remote from the first barrier layer, of the conversion element and on the top of the first barrier layer,
wherein the first barrier layer and the second barrier layer jointly completely enclose the conversion element,
wherein the first barrier layer and the second barrier layer are in places in direct contact with one another,
wherein the conversion element comprises a matrix material with wavelength-converting quantum dots,
wherein the wavelength-converting quantum dots comprise a semiconductor core, which has wavelength-converting characteristics,
wherein the semiconductor core is surrounded by a first encasing layer comprising an inorganic material, and
wherein the first encasing layer is enclosed by a second encasing layer comprising an organic material.
